(19) United States
(12) Patent Application Publication
(10) Pub. No.: US 2025/0286537 A1
(43) Pub. Date: Sep. 11, 2025

(54) ADAPTIVE GATE CURRENT CONTROL

(71) Applicant: Infineon Technologies AG, Neubiberg (DE)

(72) Inventors: Cristian Murtaza, Bucharest (RO); Diana Raluca Murtaza, Bucharest (RO)

(21) Appl. No.: 19/014,073

(22) Filed: Jan. 8, 2025

(30) Foreign Application Priority Data
Mar. 8, 2024 (DE) 102024106684.9

(51) Int. Cl. H03K 3/012; H02P 23/00; H03K 17/56

(52) U.S. Cl. CPC H03K 3/012; H03K 17/56; H02P 23/00

(57) ABSTRACT

A method for driving a transistor is described herein. In accordance with one embodiment, method includes modulating an output voltage by cyclically switching a transistor on and off, wherein, in each switching cycle, a gate current having a first current level is supplied to the transistor to switch the transistor on. The method further includes determining a characteristic time parameter of the output voltage (e.g. a rise or a delay time) and determining an error representing the difference between the determined time parameter and a target time in each switching cycle; adjusting the first current level based on the error; and detecting an oscillation of the error. When an oscillation is detected, the adjustment of the first current level is paused until the magnitude of the error exceeds a threshold value in a second number of consecutive switching cycles.

### TECHNICAL FIELD

The present disclosure relates to the field of gate current control for driving metal-oxide-semiconductor (MOS) transistors, which may be used, for example, in motor control applications.

### BACKGROUND

In various applications, gate driver circuits are used in connection with MOS transistors to switch electric loads on an off. Gate driver circuits are particularly used to control the switching process of power transistors (e.g. MOS field effect transistors (MOSFETs) or insulated-gate bipolar transistors (IGBTs)). For example, the duration of a switching process (e.g. the slew rate (rise and fall times) and delay times) may be controlled by controlling the gate current applied to the gate electrode of a power transistor. In many applications, a defined slew rate is an important design parameter as the slew rate is related to electromagnetic interference (EMI) and thus relevant for the electromagnetic compatibility (EMC) of an electronic product. Examples of applications in which gate driver circuits are used to control the switching process of power transistors are, inter alia, switched-mode power supplies, active power factor correction (PFC) circuits, power converters, motor controllers, etc.

For example, integrated circuits (ICs) for driving several transistor half-bridges, which are used to control the operation of an electric motors (e.g. brushless DC motors), are commercially available. Such motor control ICs may implement adaptive algorithms to regulate the turn-on/off delay times or the rise/fall times (or both) of the connected power transistors. Regulation loops may be either implemented in the motor control IC or via a microcontroller connected to the motor control IC. Normally, the transistors are switched on and off cyclically in accordance with a specific switching scheme such as Pulse Width Modulation (PWM).

The mentioned adaptive control algorithms tend to cause oscillations (toggling) between two consecutive regulation steps, which may increase EMI and deteriorate the EMC performance of the product. This may be an issue specifically in motor control operations. However, it is understood that this issue is not limited to motor control applications and may occur in any application, in which currents are switched by power transistors.

The inventors have set themselves the objective of improving existing concepts for controlling the switching process of power transistors, particularly with regard to the issue described above.

### SUMMARY

The object mentioned above is achieved by the method of claims 1 and 8 and the circuit of claim 12. Various embodiments and further developments are covered by the dependent claims. Accordingly, a method for driving a transistor is described herein. In one embodiment, the method includes modulating an output voltage by cyclically switching the transistor on and off. In each switching cycle, a gate current having a first current level is supplied to the transistor to switch the transistor on. The method further includes determining a characteristic time parameter of the output voltage (e.g. a rise time or a delay time), determining an error representing the difference between the determined time parameter and a target time in each switching cycle, and adjusting the first current level based on the detected error. Furthermore, the method includes, when the error changes its sign in a first number of consecutive switching cycles, pausing the adjustment of the first current level until the error exceeds a threshold value in a second number of consecutive switching cycles.

In accordance with another embodiment, method includes modulating an output voltage by cyclically switching a transistor on and off, wherein, in each switching cycle, a gate current having a first current level is supplied to the transistor to switch the transistor on. The method further includes determining a characteristic time parameter of the output voltage (e.g. a rise time or a delay time) and determining an error representing the difference between the determined rise time and a target time in each switching cycle; adjusting the first current level based on the error; and detecting an oscillation of the error. When an oscillation is detected, the adjustment of the first current level is paused until the magnitude of the error exceeds a threshold value in a second number of consecutive switching cycles.

Another embodiment relates to a circuit for driving at least one transistor that is coupled to an output node. Accordingly, the circuit includes a control circuit configured to modulate an output voltage at the output node by cyclically switching the transistor on and off; a time measurement circuit configured to measure a characteristic time parameter of the output voltage (e.g. a rise time or a delay time) in each switching cycle; and a gate driver configured to supply, in each switching cycle, a gate current having a first current level to the transistor in order to switch the transistor on, wherein the first current level is set in accordance with a set point received from the control circuit. The control circuit is further configured to: determining, in each switching cycle, an error representing the difference between the determined rise time and a target time; to adjust the set point for the first current level based on the error; and, when the error changes its sign in a first number of consecutive switching cycles, to pause the adjustment of the set point until the error exceeds a threshold value in a second number of consecutive switching cycles.

### BRIEF DESCRIPTION OF THE DRAWINGS

The invention can be better understood with reference to the following drawings and descriptions. The components in the figures are not necessarily to scale; instead emphasis is placed upon illustrating the principles of the invention. Moreover, in the figures, like reference numerals designate corresponding parts. In the drawings:

FIG. 1 illustrates one generic example of a circuit for controlling an electric motor.

FIG. 2 includes exemplary timing diagrams illustrating the gate current of a high-side transistor of a transistor half-bridge during a switch-on process, the corresponding gate-source voltage and the corresponding output voltage (phase voltage) of the transistor half-bridge.

FIG. 3 illustrates one exemplary implementation of the circuit of FIG. 1.

FIG. 4 is a flow chart illustrating one example of the control algorithm which may be implemented by the circuit of FIG. 3.

FIG. 5 illustrates an enhancement/improvement of the method of FIG. 4.

### DETAILED DESCRIPTION

In the following detailed description, reference is made to the accompanying drawings. The drawings form a part of the description and, for the purpose of illustration, show examples of how the embodiments may be used and implemented. It is to be understood that the features of the various embodiments described herein may be combined with each other, unless specifically noted otherwise. Moreover, it is understood that, although the described embodiments relate to the control of electric motors, the embodiments are not limited to motor control applications. The concepts described herein may readily be generalized and used in other applications.

As mentioned further above, integrated circuits for controlling power stages with one or more transistors (or transistor half-bridges) may tend to oscillations when using regulation loops to control, e.g., the switching times of the transistors.

In current motor control systems, the switching times may be controlled using digital regulation loops. Limit cycles may occur, particularly when a digital control loop is used. However, limit cycles and other instabilities may also occur in analog solutions. To improve the stability of the overall system, more sophisticated regulation algorithms may be used and the resolution may be increase in order to reduce the LSB current, i.e. the current Δi corresponding to the least significant bit (LSB) of a digital set-point value. However, known approaches do not eliminate the mentioned oscillations and the related electromagnetic interferences.

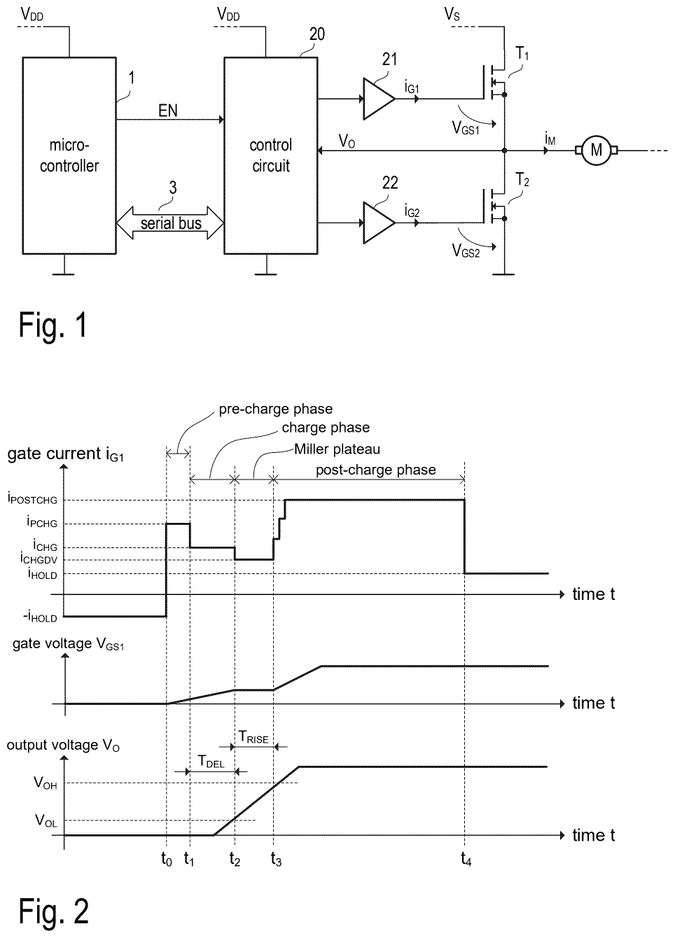

FIG. 1 illustrates a generic example of a circuit for controlling an electric motor M. It is noted that only one half-bridge (composed of high side transistor T₁ and low side transistor T₂) is shown in FIG. 1 to keep the illustration simple. It is understood that-dependent on the type of the motor-two or more half-bridges may be needed to properly operate an electric motor. For example, the control of three-phase brushless DC (BLDC) motors may require three or six transistor half-bridges. In some applications, only one transistor is needed per half-bridge wherein the other transistor is replaced by a diode. In other applications, such as a switching converter, only a single transistor or a single transistor half-bridge may be used.

In the depicted example, the high-side transistor T₁ is connected between a first supply node, which the supply voltage V_{S} during operation, and an output node, whereas the low-side transistor T₂ is connected between the output node and a second supply node, which may be at ground potential V_{GND} (or a defined reference voltage) during operation. The output node is also referred to as phase node, and the output voltage V_{O} at the output node is also referred to as phase voltage. An electric load may be connected to the output node during operation of the circuit. In the depicted example, the electric load is one stator coil of the motor M, and the current provided to the stator coil is denoted i_{M}.

In the depicted example, the transistors T₁ and T₂ are n-channel MOSFETs. It is noted, that other transistor types may be used. For example, the high-side transistor may also be a p-channel MOSFET. The transistors are switched on and off by charging and, respectively, discharging the gate electrodes of the transistors. The gate currents supplied to the gate electrodes of transistors T₁ and T₂ are denoted as i_{G1} and i_{G2}, respectively. These gate currents are provided by the gate drivers 21 and 22, which may include controllable current sources that source or sink the gate currents. If n-channel transistors are used as high-side transistors, a charge pump (or a similar circuit) may be needed to supply the gate-diver circuits 21, 22. However, charge pumps and other supply circuits for supplying gate driver circuits are as such known and thus not described herein in more detail and not shown in the drawings.

A control circuit 20 generates the input signals for the gate drivers 21 and 22 in order to set the current level of the gate currents and to ensure a proper timing of the switching processes. The timing of the switching processes may be controlled by logic signal which may be modulated to modulate the output voltage in accordance with a specific modulation scheme (e.g. PWM). In the depicted example, the control circuit 20 is supplied by a supply voltage V_{DD} (e.g. 3.3V) different from the supply voltage V_{S}. Moreover, the control circuit 20 receives the modulated output voltage V_{O} or a voltage representing the output voltage V_{O} in order to be able to determine the rise and fall times and/or delay times in each switching cycle.

In the example of FIG. 1, the control circuit 20 may communicate with a microcontroller via a serial bus 3 such as, for example, a Serial Peripheral Interphase (SPI) bus. Furthermore, the microcontroller may output one or more logic signals (such as the enable signal EN), which may be received by the control circuit 20 and which may control one or more functions implemented in the control circuit. The microcontroller 10 may be programmed to configure the control circuit 20 according to the needs of a specific application, e.g. by sending control parameters to the control circuit 20 via the serial bus 3. This control parameters may include, for example, a PWM switching frequency, target rise/fall/delay times T_{TARGET} of the output voltage VOUT, delay times in order to avoid cross-conduction in the transistor half-bridge or the like.

The control circuit 20 may include one or more logic circuits that are configured to perform the functions described herein. The one or more logic circuits may include hard-wired logic circuits, programmable (e.g. one-time programmable, OTP) logic circuits, a processor configured to execute software (firmware) stored in a memory, or any combination thereof. Moreover, the control circuit may include an interface circuit, which allows transmitting and receiving data via the serial bus 3. Dependent on the application, the control circuit 20 may also include a modulator for generating, e.g. pulse-width modulated control signals.

FIG. 2 includes timing diagrams illustrating exemplary waveforms of the gate current i_{G1} of the high-side transistor T₁ during a switch-on process, the corresponding gate-source voltage V_{GS1} and the corresponding output voltage V_{O} of the transistor half-bridge. The switching process starts at time instant t₀ upon receiving a switch-on command, e.g. a rising edge of a pulse-width modulated control signal.

Before time instant to the gate current is equals −i_{HOLD} to keep the transistor in a switched-off. state. At time instant to the current level of the gate current i_{G} is increased to i_{PCHG}, wherein the current level is maintained until time instant t₁. At time instant t₁, the current level is reduced to i_{CHG} and maintained at this level until time instant t₂. The period between t₀ and t₁ is referred to as pre-charge phase and the period between t₁ and t₂ is referred to as charge phase. At time instant t₂, the current level is reduced to i_{CHGDV} and maintained at this level until time instant t₃. The period between t₂ and t₃ is referred to as Miller plateau phase. At time instant t₃, the current level is (e.g. stepwise) increased to i_{POSTCHG} and maintained at this level until time instant t₄. The period between t₃ and t₄ is referred to as post-charge phase. At time instant t₄ the current level is reduced to i_{HOLD} to keep the transistor switched on until a switch-off command triggers switch-off process.

As can be seen in FIG. 2 the level of the pre-charge current i_{PCHG} and the charge current i_{CHG} determines the delay time T_{DEL} (between to and t₂), and the current level i_{CHGDV} in the Miller plateau phase determines the rise time T_{RISE} (between t₂ and t₃). The charge phase ends when the output voltage V_{O} has reached the level V_{OL}, and the rise time ends (approximately) when the output voltage V_{O} has reached the level V_{OH}. Accordingly, the rise time T_{RISE} depends on the length of the Miller plateau phase (which depends on the current level i_{CHGDV}).

One or more of the current levels i_{PCHG}, i_{CHG}, i_{POSTCHG}, and i_{HOLD} as well as the threshold levels V_{OL} and V_{OH} may be configurable by the microcontroller 1 via the serial bus 3. In the embodiments described herein, the current level i_{CHGDV} can be adjusted in order to achieve a desired rise time referred to as target rise time T_{TARGET}, which is also a parameter that may be set by the microcontroller 1 via the serial bus 3. Similarly, the current level i_{CHG} can be adjusted in order to achieve a desired delay time (target time). Generally speaking, one or more specific pre-determined current levels (e.g. i_{CHG}, i_{CHGDV}, etc.) are adaptively adjusted to tune one or more characteristic time parameters of the output voltage V_{O} (e.g. T_{DEL}, T_{RISE}, etc.) so that they match corresponding target time values.

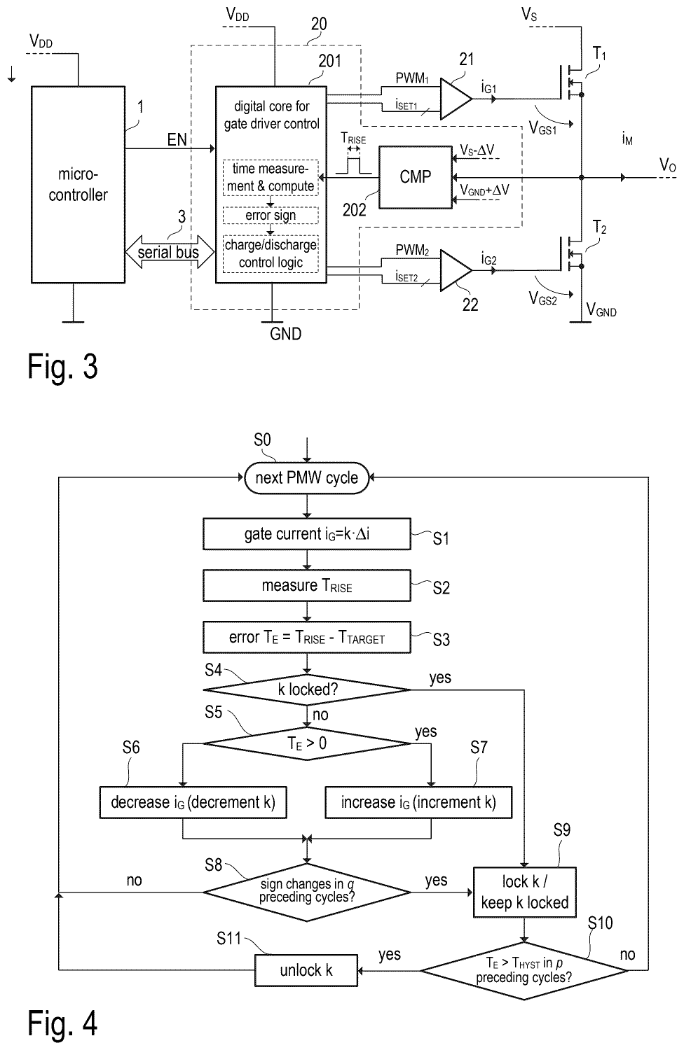

FIG. 3 illustrates one exemplary digital implementation of the circuit of FIG. 1 in more detail. Like in the example of FIG. 1, a first (high-side) transistor T₁ and a second (low-side) transistor T₂ are coupled at an output node. It is understood that one of the transistors may be replaced by a diode. In some application, one of the transistors may be omitted at all, so that first transistor T₁ forms a simple high-side switch or the second transistor forms a simple low-side switch. In the latter case, the load is coupled between the supply node, at which the supply voltage V_{S} is provided and the output node.

In the present example, the control circuit 20 is configured to modulate the output voltage V_{O} at the output node by cyclically switching the first transistor T₁ on and off. The modulator may be implemented in the digital core 201 included in the control circuit 20. Furthermore, the circuit of FIG. 3 includes a time measurement circuit 202 configured to measure a characteristic time parameter of the output voltage V_{O} (e.g. the rise time T_{RISE} in the present example) in each switching cycle. The time measurement circuit 202 may be regarded as part of the control circuit 20. In the present example, the time measurement circuit 202 includes a window comparator that is configured to compare the output voltage V_{O} with the threshold voltages V_{OL}=V_{GND}+ΔV and V_{OH}=V_{S}−ΔV, wherein ΔV is an offset, which may be fixed or configurable (e.g. by the microcontroller 1 via the serial bus 3. In the present example, the window comparator outputs a pulse whose pulse length indicates the rise time T_{RISE} (see also FIG. 2, T_{RISE}=t₃-t₂).

The circuit of FIG. 3 also includes the gate driver 21 for transistor T₁ (as well as gate driver 22 for transistor T₂). Each gate drivers is configured to supply, in each switching cycle, a gate current (i_{G1} for transistor T₁, i_{G2} for transistor T₂) with a first current level (see FIG. 2, current level i_{CHGDV}) to the respective transistor in order to switch it on. In the examples described herein the first current is determined at least for a specific time (within the switching process) which may correspond to the Miller plateau phase (see FIG. 2, time interval from t₂ to t₃). The first level may be in accordance with a set point i_{SET1}, i_{SET2} received from the control circuit 20.

The control circuit 20 (in particular its digital core 201) is further configured to determine—in each switching cycle—an error T_{E} representing the difference between the determined rise time T_{RISE} and a target time T_{TARGET} (T_{E}=T_{RISE}−T_{TARGET}). The control circuit 20 is further configured to adjust (in each cycle) the set point i_{SET1} for the first current level i_{CHGDV}, wherein the set point i_{SET1} is increased when the error T_{E} is positive and decreased when the error T_{E} is negative. Furthermore, when the error changes its sign in a first number q (e.g. q=3) of consecutive switching cycles, the control circuit 20 (e.g. its digital core 201) pauses the adjustment of the set point i_{SET1} until the error T_{E} exceeds a threshold value T_{HYST} in a second number p (e.g. p=2) of consecutive switching cycles. Pausing the cyclical adjustment of the set point i_{SET1} (and similarly i_{SET2}) prevents a continuous oscillation of the gate current and thus may improve the EMC performance. As the cyclical adjustment of the set point i_{SET1} is only paused when the oscillation (limit-cycle) has been detected, and resumed when the error T_{E} becomes too high, the EMC performance may be improved without a having to make compromises with regard to precision.

The criterion for the detection of an (undesired) oscillation is the number q of sign-changes. The variable q may be fixed or configurable by via the serial bus 3. In the present example, q is set to 3, wherein higher values of q may be chosen dependent on the needs of the application. The criterion for resuming (stop pausing) adjustment of the set-point i_{SET1} is the error T_{E} exceeding the threshold value T_{HYST} for p consecutive cycles. The variable p may be fixed or configurable by via the serial bus 3. In the present example, p is set to 2 wherein higher values of p may be used to avoid resuming the adjustment of the set-point due to short spurious events. Also p=1 would be possible; however, this would increase the risk that the adjustment of the set-point due is resumed randomly due to disturbances.

In the example of FIG. 3, the digital core 201 measures the pulse length T_{RISE} at the output of the time measurement circuit 202 (i.e. determines T_{RISE} as a digital value stored in a register), digitally calculates the error T_{E} and determines the sign and (unless the adjustment is paused) the sign changes in each switching cycle.

The control circuit 20 (e.g. the digital core 201 shown in FIG. 3) may be configured to adjust the current level i_{G1}=i_{CHGDV} by increasing or decreasing the current level by a fixed current difference Δi. The level of the gate current may be adjusted in discrete steps of Δi. That is, in the present example, the current level i_{G1}=i_{CHGDV} equals k times Δi, wherein Δi is a constant and k is an integer number (i_{G1}=i_{CHGDV}=k·Δi). The fixed current difference ΔI may correspond to the LSB current of a current output DAC (digital-to-analog converter) included in the gate drivers 21 and 22. The integer variable k may correspond to or represent the current set-points i_{SET1} and i_{SET2} which are provided by the digital core 201 and supplied to the gate drivers 21 and 22, respectively. Increasing and decreasing the current level i_{CHGDV}=k·Δi can thus be accomplished by incrementing and, respectively, decrementing k, dependent on the determined error T_{E}, in each PWM cycle.

The examples discussed herein aim at the tuning of the rise time T_{RISE} of the (switched) output voltage V_{O}. It is understood that this concept can be readily used to tune other characteristic time parameters of the switched output voltage, such as, for example the delay time T_{DEL} (see FIG. 2) occurring before the rising edge, a fall time and a delay time occurring before the falling edge. These times are characteristic time parameters of the switched output voltage, which are interrelated with corresponding gate current values applied to the transistor during the switching process.

The embodiments described herein are now summarized using the flow chart of FIG. 4, which illustrates an example of a control algorithm that may be implemented, for example, by the circuit of FIG. 3.

According to FIG. 4, a transistor (see e.g. FIG. 3, transistor T₁) is cyclically switched on and off to modulate an output voltage V_{O}. The flow chart of FIG. 4 represents one cycle, which starts at box S0. In each switching cycle, a gate current i_{G1} with a first current level i_{CHGDV}=k· Δi is supplied to the transistor T₁ to switch it on (see FIG. 4, box S1). As explained above, the first (gate) current level i_{CHGDV} is maintained for a specific time during the switch-on process, e.g. during the Miller plateau phase (cf. FIG. 2). According to FIG. 4, the method includes determining the rise time T_{RISE} of the output voltage V_{O} (see FIG. 4, box S2) and determining an error T_{E}=T_{RISE}−T_{TARGET} (see FIG. 4, box S2) representing the difference between the determined rise time T_{RISE} and a target time T_{TARGET} in each switching cycle. The further process depends on whether the cyclical adjustment of the first current level i_{CHGDV}=k. Δi has been paused, e.g. by locking the variable k (see FIG. 4, box S4). Assuming the cyclical adjustment of the first current level i_{CHGDV} is not paused, the process continues with a check whether the error T_{E} is greater than zero (see FIG. 4, box S5), wherein the first current level i_{CHGDV}=k·Δi is increased when the error T_{E} is positive (see FIG. 4, box S7) and decreased when the error T_{E} is negative (see FIG. 4, box S6). When the error T_{E} is exactly zero (which is an unlikely case), the first current level may be left unchanged. Alternatively, an error of zero may be treated like a positive error (or a negative error). Generally speaking, the current level is increased or decreased based on the latest determined error value.

When the error changes its sign in q consecutive switching cycles (see FIG. 4, box S8), then the adjustment of the first current level is paused (see FIG. 4, box S9) in the subsequent cycles until the error T_{E} exceeds a threshold value T_{HYST} in p consecutive switching cycles (see FIG. 4, box S10).

In one specific embodiment q=3 and the digital core 201 of the control circuit 20 may reset a counter to three, if no sign change occurs in a cycle, and decrement the counter, if a sign change occurs in a cycle, i.e. if the current value of T_{E} has a different sign as in the preceding cycle. If the counter value reaches zero, the result of box S8 is “yes” and the further adjustment of the first current level will be paused (box S9). If the counter value is not zero, the result of box S8 is “no” the adjustment is not paused in the next cycle.

If the cyclical adjustment of the first current level i_{CHGDV} has already been paused in a previous cycle (result of box S4 is “yes”), the increasing/decreasing of the first current level is skipped and the process is continued at boxes S9 and S10. Accordingly, it is checked whether the absolute value (magnitude) of the error |T_{E}| exceeds a given threshold T_{HSYT} in p consecutive cycles (see FIG. 4, box S10). In one specific embodiment p=2 and the digital core 201 of the control circuit 20 may reset a counter to two, if |T_{E}|≤T_{HSYT}, and decrement the counter if |T_{E}>T_{HSYT}. If the counter reaches zero, the result of box S10 is “yes” and the adjustment of the first current level i_{CHGDV}=k. Δi is resumed in the subsequent cycle(s) (see FIG. 4, box S11). If the counter is not equal to zero, the result of box S10 is “no” and the adjustment of the first current level remains paused in the subsequent cycle.

It is understood that the process steps are not necessarily executed in the depicted order. That is, the steps may be rearranged to obtain other embodiments. For example, the check made in box S8 (check whether the sign of T_{E} has changed in q consecutive cycles) may be done before box S5. Dependent on the actual implementation, some process steps may be executed concurrently. Also the pausing of the adjustment may be implemented in different ways. In a simple implementation, the register which stores the variable k may be locked so that k cannot be modified. In this example, the incrementing/decrementing operations would have no effect. In another implementation, the register which stores the variable k is not explicitly locked but the incrementing/decrementing operations are skipped. It is understood that a skilled person is able to implement the same function in various different (and substantially equivalent) ways within the scope of this disclosure.

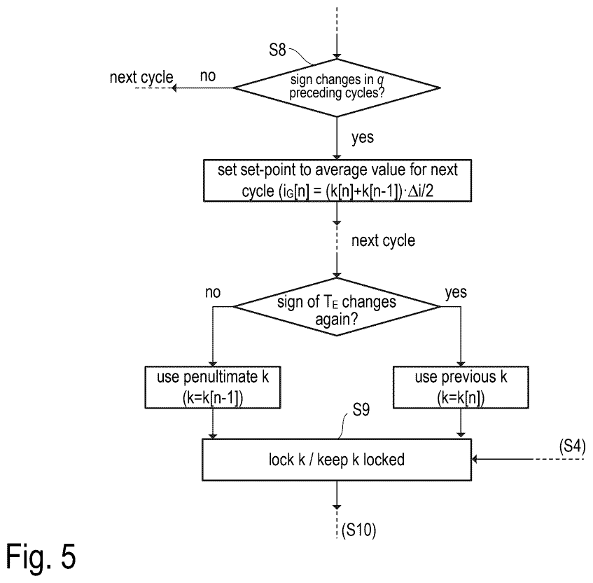

FIG. 5 illustrates an enhancement/improvement of the method of FIG. 4. In essence, the additional steps of FIG. 5 allow the selection of the more appropriate value for k (and thus for the first gate current value i_{G}=i_{CHGDV}=k·Δi), wherein the value k is either left unchanged (i.e. it is the same as in the preceding cycle) or set to the penultimate value of k. The flow chart of FIG. 8 starts at box S8. In the sign of the error T_{E} has changed in q consecutive cycles, the adjustment of the first current value i_{CHGDV}=k. Δi will be paused (e.g. by locking the variable k). However, before actually pausing the adjustment of the first current level, the first current level i_{CHGDV} (that is used in the next cycle) is set to an average of the first level in the preceding cycles, e.g. i_{CHGDV}=(k[n]+k[n−1]). Δi/2. In the next cycle k is set to either k[n] or k[n−1] based on whether the sign of the error T_{E} has changed again. Then, the variable k is locked until |T_{E}|>T_{HYST} as explained further above. For example, if the sign of the error T_{E} changes again, the previous value of k may be used (i.e. k[n], which means that k is left unchanged), or, if the sign of the error T_{E} does not change again, the penultimate value of k may be used (i.e. k[n−1]).

The concept explained above with reference to FIG. 5 is equivalent to setting the first current level to an average of the first level in the preceding cycles before pausing the adjustment of the first current level, and, in the subsequent cycle, increasing the first current level (i.e. setting k to the higher value max {k[n], k[n−1]}) when the error T_{E} is positive, and decreasing the first current level when the error is negative (i.e. setting k to the lower value min {k[n], k[n−1]}). It is understood that a skilled person is able to implement the same function in various different (and substantially equivalent) ways within the scope of this disclosure.

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. A method comprising:
modulating an output voltage by cyclically switching a transistor on and off, wherein, in each switching cycle, a gate current having a first current level is supplied to the transistor to switch on the transistor;
determining a characteristic time parameter of the output voltage and determining an error representing a difference between the determined characteristic time parameter and a target time in each switching cycle;
adjusting the first current level based on the error; and
when the error changes its sign in a first number of consecutive switching cycles, pausing the adjustment of the first current level until a magnitude of the error exceeds a threshold value in a second number of consecutive switching cycles.

2. The method of claim 1,
wherein the characteristic time parameter is a rise time or a delay time of the output voltage.

3. The method of claim 1,
wherein, for adjusting the first current level based on the error, the first current level is increased when the error is positive and decreased when the error is negative.

4. The method of claim 1,
wherein, before pausing the adjustment of the first current level, the method includes setting the first current level to an average of the first level in preceding cycles.

5. The method of claim 1,
wherein, before pausing the adjustment of the first current level, the method includes setting the first current level to an average of the first level in preceding cycles; and
in a subsequent cycle, the method includes increasing the first current level when the error is positive, and decreasing the first current level when the error is negative.

6. The method of claim 1,
wherein adjusting the first current level includes increasing or decreasing the first current level by a fixed current difference.

7. The method of claim 1,
wherein the first current level equals k times a fixed current difference wherein k is an integer, and
wherein increasing and decreasing the first level is accomplished by incrementing and, respectively, decrementing k.

8. A method comprising:
modulating an output voltage by cyclically switching a transistor on and off, wherein, in each switching cycle, a gate current having a first current level is supplied to the transistor to switch on the transistor;
determining a characteristic time parameter of the output voltage and determining an error representing a difference between the determined characteristic time parameter and a target time in each switching cycle;
adjusting the first current level based on the error;
detecting an oscillation of the error and, when the oscillation is detected, pausing the adjustment of the first current level until a magnitude of the error exceeds a threshold value in a subsequent number of consecutive switching cycles.

9. The method of claim 8,
wherein the characteristic time parameter is a rise time or a delay time of the output voltage.

10. The method of claim 8,
wherein detecting the oscillation of the error comprises detection that the error changes its sign in a first number of consecutive switching cycles.

11. The method of claim 8,
wherein adjusting the first current level is resumed when the magnitude of the error exceeds the threshold value in the subsequent number of consecutive switching cycles.

12. A circuit comprising:
a first transistor coupled to an output node,
a control circuit configured to modulate an output voltage at the output node by cyclically switching the transistor on and off,
a time measurement circuit configured to measure a characteristic time parameter of the output voltage in each switching cycle;
a gate driver configured to supply, in each switching cycle, a gate current having a first current level to the transistor in order to switch the transistor on, the first current level being set in accordance with a set point received from the control circuit;
wherein the control circuit is further configured to:
determine, in each switching cycle, an error representing a difference between the measured characteristic time parameter and a target time;
adjust the set point for the first current level based on the error; and
when the error changes its sign in a first number of consecutive switching cycles, pause the adjustment of the set point until the error exceeds a threshold value in a second number of consecutive switching cycles.

13. The circuit of claim 11 comprising:
wherein, to adjust the set point for the first current level, the control circuit is further configured to increase the set point when the error is positive and to decrease the set point when the error is negative.

14. A system comprising:
an electric motor including a stator coil; and
a circuit comprising:
a first transistor coupled to an output node,
a control circuit configured to modulate an output voltage at the output node by cyclically switching the transistor on and off,
a time measurement circuit configured to measure a characteristic time parameter of the output voltage in each switching cycle;
a gate driver configured to supply, in each switching cycle, a gate current having a first current level to the transistor in order to switch the transistor on, the first current level being set in accordance with a set point received from the control circuit;
wherein the control circuit is further configured to:
determine, in each switching cycle, an error representing a difference between the measured characteristic time parameter and a target time;
adjust the set point for the first current level based on the error; and
when the error changes its sign in a first number of consecutive switching cycles, pause the adjustment of the set point until the error exceeds a threshold value in a second number of consecutive switching cycles,
wherein the stator coil of the motor is connected to the output node of the circuit.
